(19) United States
(12) Patent Application Publication
(10) Pub. No.: US 2009/0231809 A1
(43) Pub. Date: Sep. 17, 2009

(54) Electronic Apparatus

(75) Inventors: Shingo Koide, Tachikawa-shi (JP); Tetsunari Ichimura, Ome-shi (JP)

Correspondence Address: BLAKELY SOKOLOFF TAYLOR & ZAFMAN LLP, 1279 OAKMEAD PARKWAY, SUNNYVALE, CA, 94085-4040, US

(73) Assignee: KABUSHIKI KAISHA TOSHIBA, Tokyo (JP)

(21) Appl. No.: 12/259,835

(22) Filed: Oct. 28, 2008

(30) Foreign Application Priority Data
Mar. 12, 2008 (JP) 2008-062581

(51) Int. Cl. H05K 7/20

(52) U.S. Cl. 361/697

(57) ABSTRACT

According to an aspect of the present invention, an electronic apparatus includes: a plurality of heat generating components; a plurality of heat sinks respectively provided for the plurality of heat generating components;

a fan that simultaneously blows air to the heat sinks; a plurality of shutters that respectively block air flows blown from the fan to the heat sinks; a determining section configured to, based on temperatures of the heat generating components, determine whether one of the heat generating components needs to be cooled or not; and a controlling section configured to operate at least one of the shutters to control air volume blown over one of the heat sinks that corresponds to the one of the heat generating components that needs to be cooled.

### CROSS-REFERENCE TO RELATED APPLICATIONS

This application is based upon and claims the benefit of priority from Japanese Patent Application No. 2008-062581, filed on Mar. 12, 2008, the entire contents of which are incorporated herein by reference.

### BACKGROUND

1. Field

An aspect of the present invention relates to an electronic apparatus in which air volumes exhausted from each of air exhaust ports of a bidirectional air exhaust fan are dynamically controlled to cool heat generating components.

2. Description of the Related Art

Recently, with sophistication of an electronic apparatus, a plurality of CPU boards and a fan are mounted on the electronic apparatus. Irrespective of different generated heat amounts of the CPU boards, the fan blows only a constant air volume, and hence a temperature difference is produced among the CPU boards. Therefore, operation margins of the CPU boards are different from each other, and there may arise a problem in that operation reliabilities are lowered.

An electronic apparatus has been proposed in which the air volume is adjusted in accordance with the change of the generated heat amount, whereby the cooling efficiency is improved and the temperature differences among boards and LSIs in the apparatus are reduced (see JP-A-2005-286268, for instance). In the electronic apparatus, air exhaust ports are disposed for each of heat generating components, and air volumes blown to the heat generating components are independently controlled.

In the case where a bidirectional air exhaust fan is used as an air exhaust fan, usually the air volumes blown to air exhaust ports are not equal to each other, and there is a tendency of “air volume blown to a first exhaust port>air volume blown to a second exhaust port”. Even in the case where a temperature of a heat generating component cooled at the second exhaust port is higher than that of a heat generating component cooled at the first exhaust port, a larger air volume is exhausted to the first exhaust port which is not required to perform further cooling, and hence it is necessary to increase the number of rotations of the bidirectional air exhaust fan more than necessary.

### BRIEF DESCRIPTION OF THE SEVERAL VIEWS OF THE DRAWINGS

A general architecture that implements the various feature of the present invention will now be described with reference to the drawings. The drawings and the associated descriptions are provided to illustrate embodiments of the present invention and not to limit the scope of the present invention.

FIG. 1 is an exemplary perspective view of an electronic apparatus of a first embodiment of the invention;

FIG. 2 is an exemplary block diagram showing the electronic apparatus of the first embodiment;

FIG. 3 is an exemplary diagram showing a cooling mechanism in the first embodiment;

FIG. 4 is an exemplary flowchart showing a procedure in the case where the electronic apparatus of the first embodiment performs an air exhaust control process;

FIG. 5 is an exemplary diagram illustrating the air exhaust control process in the electronic apparatus of the first embodiment;

FIG. 6 is an exemplary diagram illustrating the air exhaust control process in the electronic apparatus of the first embodiment;

FIG. 7 is an exemplary diagram illustrating the air exhaust control process in the electronic apparatus of the first embodiment;

FIG. 8 is an exemplary diagram illustrating the air exhaust control process in the electronic apparatus of the first embodiment;

FIG. 9 is an exemplary diagram illustrating the air exhaust control process in the electronic apparatus of the first embodiment;

FIG. 10 is an exemplary flowchart showing the procedure in the case where the electronic apparatus of the first embodiment performs the air exhaust control process;

FIG. 11 is an exemplary block diagram showing an electronic apparatus of a second embodiment of the invention;

FIG. 12 is an exemplary diagram showing a cooling mechanism in the second embodiment;

FIG. 13 is an exemplary flowchart showing the procedure in the case where the electronic apparatus of the second embodiment performs an air exhaust control process;

FIG. 14 is an exemplary diagram illustrating the air exhaust control process in the electronic apparatus of the second embodiment;

FIG. 15 is an exemplary diagram illustrating the air exhaust control process in the electronic apparatus of the second embodiment;

FIG. 16 is an exemplary diagram illustrating the air exhaust control process in the electronic apparatus of the second embodiment;

FIG. 17 is an exemplary diagram illustrating the air exhaust control process in the electronic apparatus of the second embodiment;

FIG. 18 is an exemplary diagram illustrating the air exhaust control process in the electronic apparatus of the second embodiment; and

FIG. 19 is an exemplary flowchart showing the procedure in the case where the electronic apparatus of the second embodiment performs the air exhaust control process.

### DETAILED DESCRIPTION

Various embodiments according to the present invention will be described hereinafter with reference to the accompanying drawings. In general, according to one embodiment of the present invention, an electronic apparatus includes: a plurality of heat generating components; a plurality of heat sinks respectively provided for the plurality of heat generating components; a fan that simultaneously blows air to the heat sinks; a plurality of shutters that respectively block air flows blown from the fan to the heat sinks; a determining section configured to, based on temperatures of the heat generating components, determine whether one of the heat generating components needs to be cooled or not; and a controlling section configured to operate at least one of the shutters to control air volume blown over one of the heat sinks that corresponds to the one of the heat generating components that needs to be cooled.

### First Embodiment

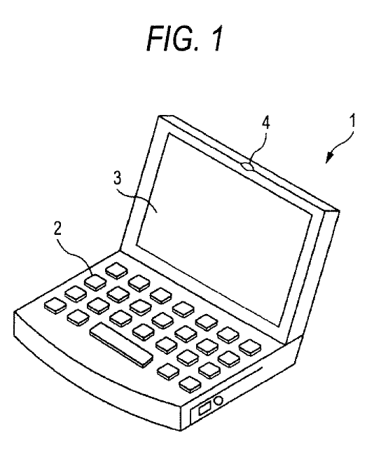

A first embodiment of an electronic apparatus of the invention will be described with reference to FIGS. 1 to 10. FIG. 1 is a perspective view of the electronic apparatus 1 of the invention. The electronic apparatus 1 is a notebook Personal Computer (PC) which is usually used, or the like. In the electronic apparatus 1, as shown in FIG. 1, a keyboard 2 having a plurality of keys which are depressed when the user inputs instructions, a display device 3 which displays a screen showing characters, images, and the like, and a speaker 4 which outputs sounds are disposed so as to be exposed to the outside.

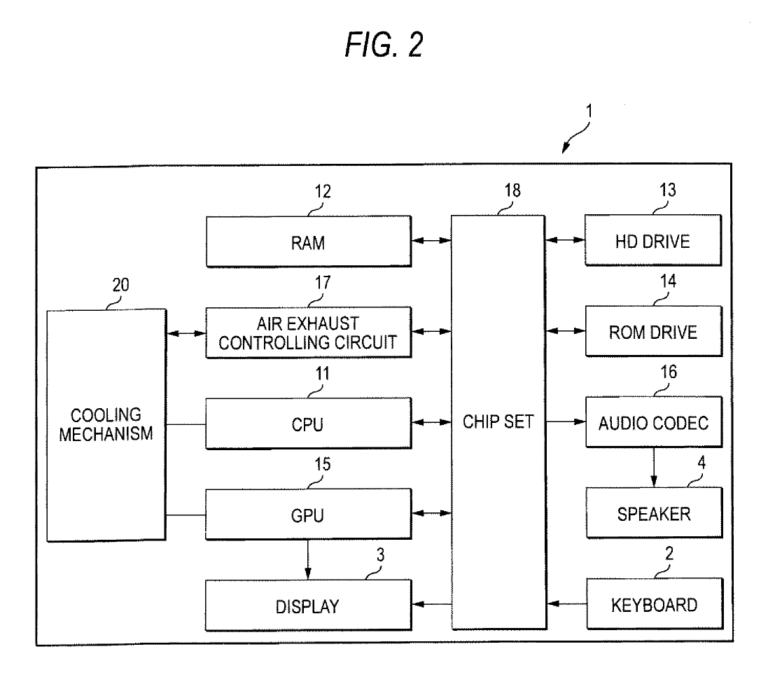

FIG. 2 is a block diagram of the electronic apparatus 1. As shown in FIG. 2, the electronic apparatus 1 includes a Central Processing Unit (CPU) 11, a Random Access Memory (RAM) 12, a Hard Disk (HD) drive 13, a Read Only Memory (ROM) drive 14, a GPU 15, an audio codec 16, and an air exhaust controlling circuit 17. These components are interconnected by a chip set 18.

The CPU 11 generally controls the electronic apparatus 1, and performs a drawing control process which will be described later, and other various calculation and control processes. The CPU 11 includes input interfaces for input devices such as the keyboard 2 and a mouse which is externally connected, and performs various processes based on a signal input through the input devices. The RAM 12 is used as a working area when the CPU 11 performs a process, and temporarily stores data required in the process.

The HD drive 13 is a driving device for applying writing and reading operations on a Hard Disk (HD) which stores process program required in processes to be performed by the CPU 11, and data necessary for the processes. The ROM drive 14 is a driving device for applying writing and reading operations on a recording medium such as a Digital Versatile

The GPU 15 includes a video RAM which temporarily stores character or graphic data to be displayed on the display device 3, and which is used in a process of two-dimensional graphics (2D) or three-dimensional graphics (3D) or a motion picture process, and, under the control of the CPU 11, outputs frame data loaded in the video RAM to the display device 3.

The audio codec 16 includes an output interface which causes the speaker 4 disposed on the electronic apparatus 1 to output a sound, and, under the control of the CPU 11, converts a digital audio signal to an analog signal, and then outputs it as a sound from the speaker 4.

The air exhaust controlling circuit 17 controls a cooling mechanism 20 which cools heat generating components a, b such as the CPU 11 and the CPU 15. Specifically, the air exhaust controlling circuit 17 obtains the temperatures of the heat generating components a, b, determines whether the heat generating components are to be cooled or not, and, if it is determined that the heat generating components are to be cooled, performs an air exhaust control process of cooling the heat generating components a, b.

The chip set 18 is an integrated circuit including a memory controller, a bus bridge, an Integrated Drive Electronics (IDE) controller, various I/O controllers, etc.

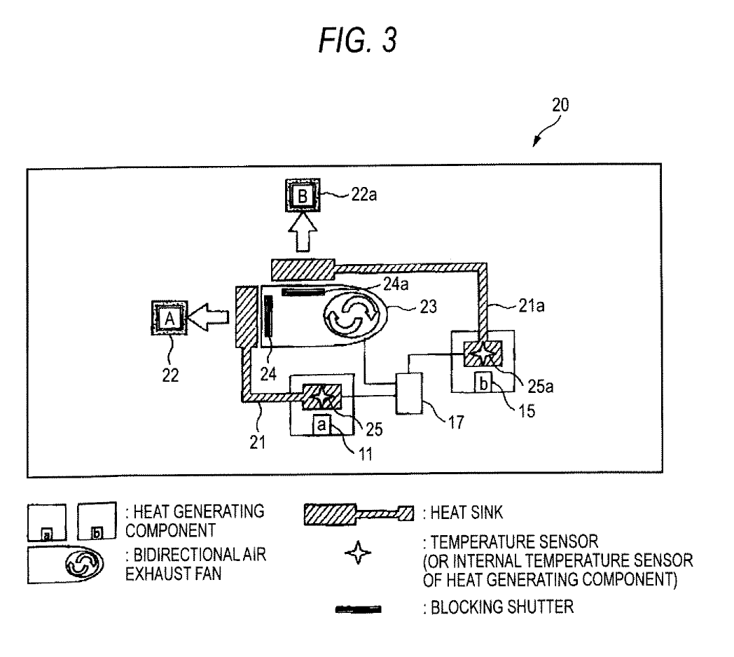

The cooling mechanism 20 is a mechanism which, under the control of the air exhaust controlling circuit 17, cools the heat generating components a, b such as the CPU 11 and the GPU 15. As shown in FIG. 3, the cooling mechanism 20 includes heat sinks 21, 21a for the heat generating components a, b, respectively. The heat generating components a, b are cooled by the heat sinks 21, 21a, respectively. The heat sink 21 is provided with an air exhaust port (A) 22 to blow hot air to the outside, and similarly the heat sink 21a is provided with an air exhaust port (B) 22a. The cooling mechanism 20 further includes a bidirectional air exhaust fan 23, so that the air blown by the bidirectional air exhaust fan 23 is passed over the heat sink 21 or the heat sink 21a and then exhausted from the respective air exhaust ports 22, 22a.

A blocking shutter 24 is disposed between the bidirectional air exhaust fan 23 and the heat sink 21, and a blocking shutter 24a is disposed between the bidirectional air exhaust fan 23 and the heat sink 21a. The blocking shutters 24, 24a are shutters in which the aperture ratio is changeable in order to control the air volume blown from the bidirectional air exhaust fan 23 to the corresponding heat sink 21 or 21a. In this example, it is assumed that the blocking shutters 24, 24a are changeable to either of three states or an aperture ratio of 0% (a completely closed state), an aperture ratio of 50% (a state where the blocking shutter is half-opened), and an aperture ratio of 100% (a state where the blocking shutter is opened).

The cooling mechanism 20 includes temperature sensors 25, 25a in vicinities of the heat generating components a, b such as the CPU 11 and the GPU 15, respectively. The air exhaust controlling circuit 17 obtains the temperature of the heat generating component a (the CPU 11) from the temperature sensor 25, and also that of the heat generating component b (the CPU 15) from the temperature sensor 25a. The temperature sensors 25, 25a may be incorporated in the CPU 11 and the GPU 15. Based on the temperatures, the air exhaust controlling circuit 17 adjusts the aperture ratios of the blocking shutters 24, 24a, or the number of rotations of the bidirectional air exhaust fan 23, whereby the heat generating components a, b are cooled while the exhaust air volumes to the heat sinks 21, 21a are controlled.

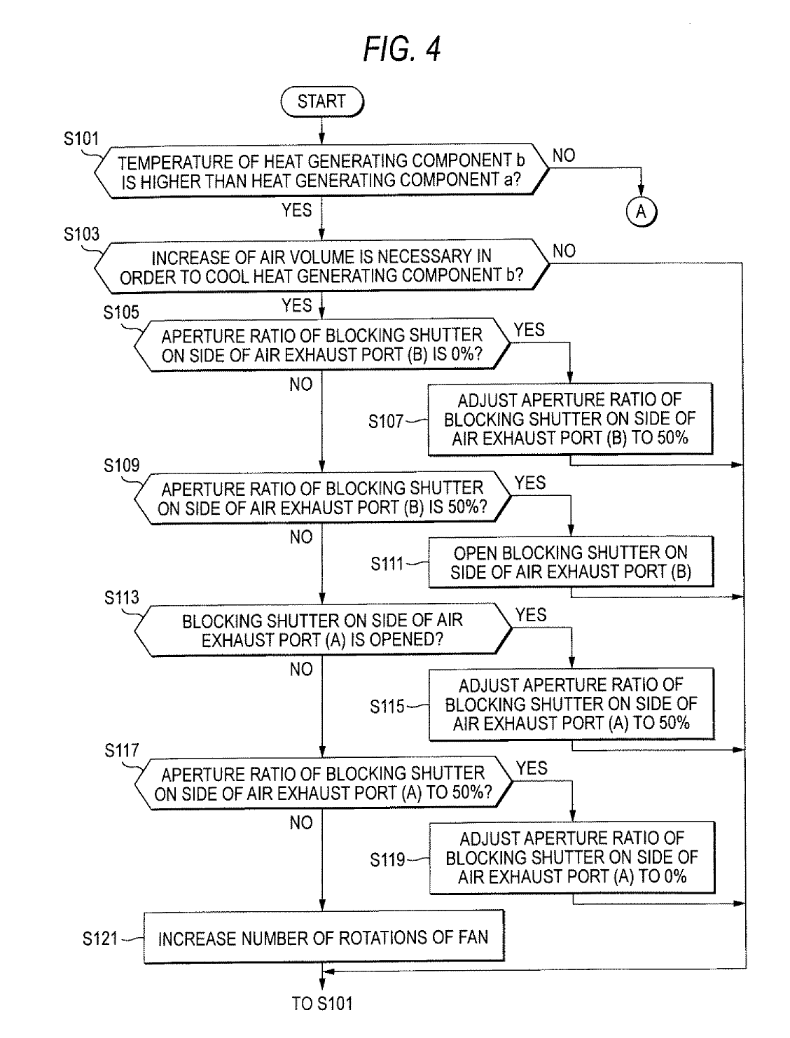

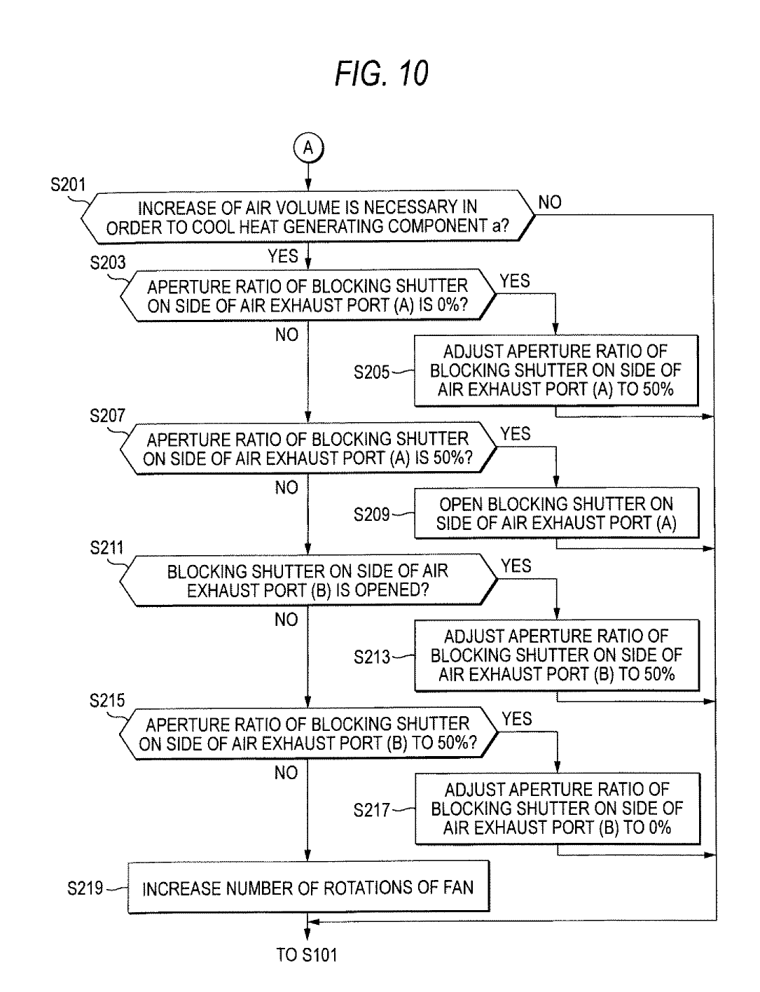

The air exhaust controlling circuit 17 of the electronic apparatus 1 obtains the temperatures of the heat generating components a, b such as the CPU 11 and the CPU 15, at, for example, regular intervals, and, based on the temperatures, performs the air exhaust control process in which the aperture ratios of the blocking shutters 24, 24a are adjusted, or the air volume of the bidirectional air exhaust fan 23 is adjusted. The procedure in which the electronic apparatus 1 performs the air exhaust control process will be described with reference to the flowcharts shown in FIGS. 4 and 10. Hereinafter, the description will be made while the term “step” is omitted so that, for example, “step S101” is referred to as “S101”.

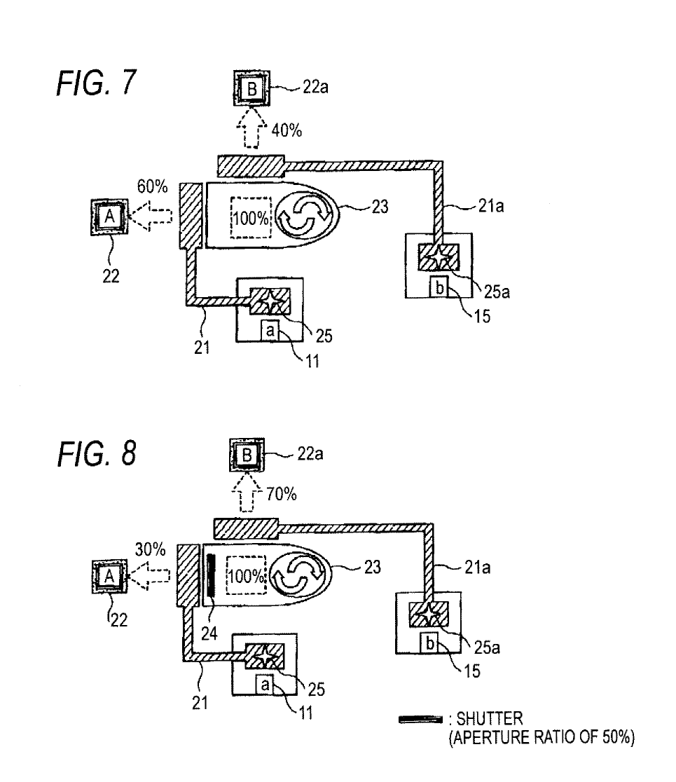

Here, it is assumed that, when both the blocking shutter 24 on the side of the air exhaust port (A) 22, and the blocking shutter 24a on the side of the air exhaust port (B) 22a are opened, an air flow of 60% volume of an air flow generated by the bidirectional air exhaust fan 23 flows to the air exhaust port (A) 22, and an air flow of 40% flows to the air exhaust port (B) 22a as shown in FIG. 7.

First, the air exhaust controlling circuit 17 determines whether the temperature of the heat generating component b (the CPU 15) is higher than that of the heat generating component a (the CPU 11) or not (S101). This determination is performed by the air exhaust controlling circuit 17 with obtaining the temperatures of the CPU 11 and the CPU 15 from the temperature sensors 25, 25a, and comparing the temperatures.

The case where the temperature of the heat generating component b (the GPU 15) is higher than that of the heat generating component a (the CPU 11) will be described with reference to the flowchart shown in FIG. 4. If the temperature of the heat generating component b is higher than that of the heat generating component a (Yes in S101), the air exhaust controlling circuit 17 determines whether it is necessary to increase the air volume in order to cool the heat generating component b or not (S103). In the case where the temperature of the heat generating component b is equal to or higher than a threshold value, for example, it is determined that the air volume is necessary to be increased.

If it is not necessary to increase the air volume for cooling the heat generating component b (No in S103), it is not necessary to cool the heat generating component a in which the temperature is lower than the heat generating component b, and hence the process returns to step S101 in which the air exhaust controlling circuit 17 again determines whether the temperature of the heat generating component b is higher than that of the heat generating component a or not.

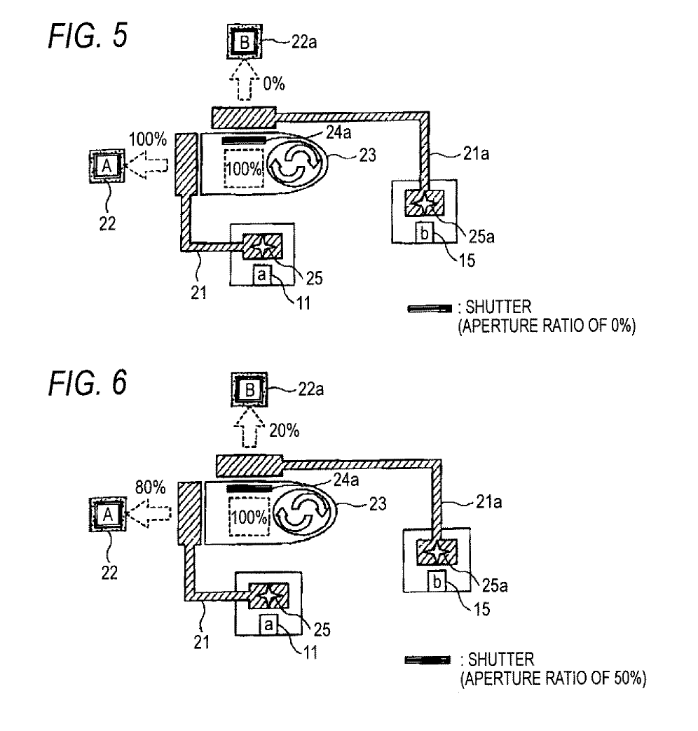

If it is necessary to increase the air volume for cooling the heat generating component b (Yes in S103), the air exhaust controlling circuit 17 determines whether the aperture ratio of the blocking shutter 24a on the side of the air exhaust port (B) 22a is 0% as shown in FIG. 5 or not, i.e., whether the blocking shutter 24a is completely closed or not, in order to seek means for cooling the heat generating component b without increasing the number of rotations of the bidirectional air exhaust fan 23 (S105). In this case, the air flow generated by the bidirectional air exhaust fan 23 does not flow to the air exhaust port (B) 22a by the blocking shutter 24a on the side of the air exhaust port (B) 22a, and hence an air flow of an air volume of 100% flows to the air exhaust port (A) 22.

If the aperture ratio of the blocking shutter 24a on the side of the air exhaust port (B) 22a is 0% (Yes in S105), the air exhaust controlling circuit 17 adjusts the aperture ratio of the blocking shutter 24a to 50% (S107). As a result, as shown in FIG. 6, an air flow of an air volume of 80% flows to the air exhaust port (A) 22, and an air flow of 20% flows to the air exhaust port (B) 22a. In this way, when the aperture ratio of the blocking shutter 24a on the side of the air exhaust port (B) 22a is increased, an air flow of a larger air volume can be supplied to the heat sink 21a on the side of the heat generating component b (the GPU 15), and the heat generating component b can be cooled. Then, the process returns to step S101 in which the air exhaust controlling circuit 17 again determines whether the temperature of the heat generating component b is higher than that of the heat generating component a or not.

If the aperture ratio of the blocking shutter 24a on the side of the air exhaust port (B) 22a is not 0% (No in S105), the air exhaust controlling circuit 17 determines whether the aperture ratio of the blocking shutter 24a on the side of the air exhaust port (B) 22a is 50% as shown in FIG. 6 or not (S109). In this case, the air flow generated by the bidirectional air exhaust fan 23 hardly flows to the air exhaust port (B) 22a by the blocking shutter 24a on the side of the air exhaust port (B) 22a. Therefore, an air flow of an air volume of 80% flows to the air exhaust port (A) 22, and an air flow of an air volume of 20% flows to the air exhaust port (B).

If the aperture ratio of the blocking shutter 24a on the side of the air exhaust port (B) 22a is 50% (Yes in S109), the air exhaust controlling circuit 17 opens the blocking shutter 24a on the side of the air exhaust port (B) 22a, i.e., adjusts the aperture ratio to 100% (S111). As a result, as shown in FIG. 7, an air flow of an air volume of 60% flows to the air exhaust port (A) 22, and an air flow of 40% flows to the air exhaust port (B) 22a. In this way, when the blocking shutter 24a on the side of the air exhaust port (B) 22a is completely opened, an air flow of a larger air volume can be supplied to the heat sink 21a on the side of the heat generating component b (the GPU 15), and the heat generating component b can be cooled. Then, the process returns to step S101 in which the air exhaust controlling circuit 17 again determines whether the temperature of the heat generating component b is higher than that of the heat generating component a or not.

If the aperture ratio of the blocking shutter 24a on the side of the air exhaust port (B) 22a is not 50% (No in S109), the air exhaust controlling circuit 17 determines whether the aperture ratio of the blocking shutter 24 on the side of the air exhaust port (A) 22 is 100% as shown in FIG. 7 or not, i.e., whether the blocking shutter 24 is opened or not (S113). In this case, an air flow of an air volume of 60% flows to the air exhaust port (A) 22, and an air flow of an air volume of 40% flows to the air exhaust port (B) 22a.

If the blocking shutter 24 on the side of the air exhaust port (A) 22 is opened (Yes in S113), the air exhaust controlling circuit 17 adjusts the aperture ratio of the blocking shutter 24 to 50% (S115). As a result, as shown in FIG. 8, an air flow of an air volume of 30% flows to the air exhaust port (A) 22, and an air flow of an air volume of 70% flows to the air exhaust port (B) 22a. In this way, when the aperture ratio of the blocking shutter 24 on the side of the air exhaust port (A) 22 is decreased to restrict the air volume blown to the air exhaust port (A) 22, an air flow of a larger air volume can be supplied to the heat sink 21a on the side of the heat generating component b (the GPU 15), and the heat generating component b can be cooled. Then, the process returns to step S101 in which the air exhaust controlling circuit 17 again determines whether the temperature of the heat generating component b is higher than that of the heat generating component a or not.

If the blocking shutter 24 on the side of the air exhaust port (A) 22 is not opened (No in S113), the air exhaust controlling circuit 17 determines whether the aperture ratio of the blocking shutter 24 on the side of the air exhaust port (A) 22 is 50% as shown in FIG. 8 or not (S117). In this case, the air flow generated by the bidirectional air exhaust fan 23 hardly flows to the air exhaust port (A) 22 by the blocking shutter 24 on the side of the air exhaust port (A) 22. Therefore, an air flow of an air volume of 30% flows to the air exhaust port (A) 22, and an air flow of an air volume of 70% flows to the air exhaust port (B) 22a.

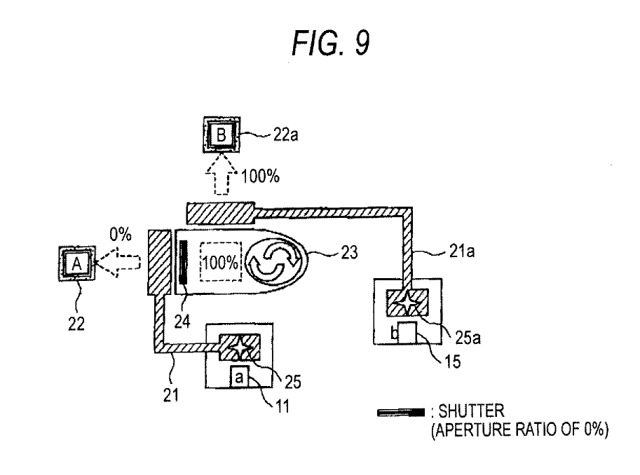

If the aperture ratio of the blocking shutter 24 on the side of the air exhaust port (A) 22 is 50% (Yes in S117), the air exhaust controlling circuit 17 adjusts the aperture ratio of the blocking shutter 24 to 0% (S119). As a result, as shown in FIG. 9, an air flow of an air volume of 0% flows to the air exhaust port (A) 22, and an air flow of an air volume of 100% flows to the air exhaust port (B) 22a. In this way, when the aperture ratio of the blocking shutter 24 on the side of the air exhaust port (A) 22 is decreased and the air flow to the air exhaust port (A) 22 is blocked, an air flow of a larger air volume can be supplied to the heat sink 21a on the side of the heat generating component b (the GPU 15), and the heat generating component b can be cooled. Then, the process returns to step S101 in which the air exhaust controlling circuit 17 again determines whether the temperature of the heat generating component b is higher than that of the heat generating component a or not.

If the aperture ratio of the blocking shutter 24 on the side of the air exhaust port (A) 22 is not 50%, i.e., if the aperture ratio of the blocking shutter 24 on the side of the air exhaust port (A) 22 is 0% as shown in FIG. 9 (No in S117), the heat generating component b cannot be cooled simply by controlling the blocking shutters 24, 24a, and hence the air exhaust controlling circuit 17 increases the number of rotations of the bidirectional air exhaust fan 23 (S121). When the number of rotations of the bidirectional air exhaust fan 23 is increased, an air flow of a larger air volume can be supplied to the heat sink 21a for the heat generating component b (the GPU 15), and the heat generating component b can be cooled. Then, the process returns to step S101 in which the air exhaust controlling circuit 17 again determines whether the temperature of the heat generating component b is higher than that of the heat generating component a or not.

In the case where it is necessary to cool the heat generating component b, if the heat generating component b can be cooled by adjusting the aperture ratios or operating the blocking shutters 24, 24a, the electronic apparatus 1 adjusts the aperture ratios or operating the blocking shutters 24, 24a to cool the heat generating component b. If not, the heat generating component b is cooled by increasing the number of rotations of the bidirectional air exhaust fan 23.

Next, the case where the temperature of the heat generating component a (the CPU 11) is higher than that of the heat generating component b (the GPU 15) will be described with reference to the flowchart shown in FIG. 10. If the temperature of the heat generating component a (the CPU 11) is higher than that of the heat generating component b (the GPU 15) (No in S101), the air exhaust controlling circuit 17 determines whether it is necessary to increase the air volume for cooling the heat generating component a or not (S201). In the case where the temperature of the heat generating component b is equal to or higher than a threshold value, for example, it is determined that an increase of the air volume is necessary.

If it is not necessary to increase the air volume for cooling the heat generating component a (No in S201), it is not necessary to cool the heat generating component b in which the temperature is lower than the heat generating component a, and hence the process returns to step S101 in which the air exhaust controlling circuit 17 again determines whether the temperature of the heat generating component b is higher than that of the heat generating component a or not.

If it is necessary to increase the air volume for cooling the heat generating component a (Yes in S201), the air exhaust controlling circuit 17 determines whether the aperture ratio of the blocking shutter 24 on the side of the air exhaust port (A) 22 is 0% as shown in FIG. 9 or not, i.e., whether the blocking shutter 24 is completely closed or not, in order to seek means for cooling the heat generating component a without increasing the number of rotations of the bidirectional air exhaust fan 23 (S203). In this case, the air flow generated by the bidirectional air exhaust fan 23 does not flow to the air exhaust port (A) 22 by the blocking shutter 24 on the side of the air exhaust port (A) 22, and hence an air flow of an air volume of 100% flows to the air exhaust port (B) 22a.

If the aperture ratio of the blocking shutter 24 on the side of the air exhaust port (A) 22 is 0% (Yes in S203), the air exhaust controlling circuit 17 adjusts the aperture ratio of the blocking shutter 24 to 50% (S205). As a result, as shown in FIG. 8, an air flow of 30% flows to the air exhaust port (A) 22, and an air flow of an air volume of 70% flows to the air exhaust port (B) 22a. In this way, when the aperture ratio of the blocking shutter 24 on the side of the air exhaust port (A) 22 is increased, an air flow of a larger air volume can be supplied to the heat sink 21 on the side of the heat generating component a (the CPU 11), and the heat generating component a can be cooled. Then, the process returns to step S101 in which the air exhaust controlling circuit 17 again determines whether the temperature of the heat generating component b is higher than that of the heat generating component a or not.

If the aperture ratio of the blocking shutter 24 on the side of the air exhaust port (A) 22 is not 0% (No in S203), the air exhaust controlling circuit 17 determines whether the aperture ratio of the blocking shutter 24 on the side of the air exhaust port (A) 22 is 50% as shown in FIG. 8 or not (S207). In this case, the air flow generated by the bidirectional air exhaust fan 23 hardly flows to the air exhaust port (A) 22 by the blocking shutter 24 on the side of the air exhaust port (A) 22. Therefore, an air flow of an air volume of 30% flows to the air exhaust port (A) 22, and an air flow of an air volume of 70% flows to the air exhaust port (B) 22a.

If the aperture ratio of the blocking shutter 24 on the side of the air exhaust port (A) 22 is 50% (Yes in S207), the air exhaust controlling circuit 17 opens the blocking shutter 24, i.e., adjusts the aperture ratio to 100% (S209). As a result, as shown in FIG. 7, an air flow of an air volume of 60% flows to the air exhaust port (A), and an air flow of 40% flows to the air exhaust port (B). In this way, when the aperture ratio of the blocking shutter 24 on the side of the air exhaust port (A) 22 is completely opened, an air flow of a larger air volume can be supplied to the heat sink 21 on the side of the heat generating component a (the CPU 11), and the heat generating component a can be cooled. Then, the process returns to step S101 in which the air exhaust controlling circuit 17 again determines whether the temperature of the heat generating component b is higher than that of the heat generating component a or not.

If the aperture ratio of the blocking shutter 24 on the side of the air exhaust port (A) 22 is not 50% (No in S207), the air exhaust controlling circuit 17 determines whether the aperture ratio of the blocking shutter 24a on the side of the air exhaust port (B) 22a is 100% as shown in FIG. 7 or not, i.e., whether the blocking shutter 24 is opened or not (S211). In this case, an air flow of an air volume of 60% flows to the air exhaust port (A), and an air flow of an air volume of 40% flows to the air exhaust port (B).

If the blocking shutter 24a on the side of the air exhaust port (B) 22a is opened (Yes in S211), the air exhaust controlling circuit 17 adjusts the aperture ratio of the blocking shutter 24a to 50% (S213). As a result, as shown in FIG. 6, an air flow of an air volume of 80% flows to the air exhaust port (A), and an air flow of an air volume of 20% flows to the air exhaust port (B). In this way, when the aperture ratio of the blocking shutter 24a on the side of the air exhaust port (B) 22a is decreased to restrict the air volume blown to the air exhaust port (B) 22a, an air flow of a larger air volume can be supplied to the heat sink 21 on the side of the heat generating component a (the CPU 11), and the heat generating component a can be cooled. Then, the process returns to step S101 in which the air exhaust controlling circuit 17 again determines whether the temperature of the heat generating component b is higher than that of the heat generating component a or not.

If the blocking shutter 24a on the side of the air exhaust port (B) 22a is not opened (No in S211), the air exhaust controlling circuit 17 determines whether the aperture ratio of the blocking shutter 24a on the side of the air exhaust port (B) 22a is 50% as shown in FIG. 6 or not (S215). In this case, the air flow generated by the bidirectional air exhaust fan 23 hardly flows to the air exhaust port (B) 22a by the blocking shutter 24a on the side of the air exhaust port (B) 22a. Therefore, an air flow of an air volume of 80% flows to the air exhaust port (A), and an air flow of an air volume of 20% flows to the air exhaust port (B).

If the aperture ratio of the blocking shutter 24a on the side of the air exhaust port (B) 22a is 50% (Yes in S215), the air exhaust controlling circuit 17 adjusts the aperture ratio of the blocking shutter 24a to 0% (S217). As a result, as shown in FIG. 5, an air flow of an air volume of 100% flows to the air exhaust port (A) 22, and an air flow of an air volume of 0% flows to the air exhaust port (B) 22a. In this way, when the aperture ratio of the blocking shutter 24a on the side of the air exhaust port (B) 22a is completely closed and the air flow to the air exhaust port (B) 22a is blocked, an air flow of a larger air volume can be supplied to the heat sink 21 on the side of the heat generating component a (the CPU 11), and the heat generating component a can be cooled. Then, the process returns to step S101 in which the air - 20 - exhaust controlling circuit 17 again determines whether the temperature of the heat generating component b is higher than that of the heat generating component a or not.

If the aperture ratio of the blocking shutter 24a on the side of the air exhaust port (B) 22a is not 50%, i.e., if the aperture ratio of the blocking shutter 24a on the side of the air exhaust port (B) 22a is 0% as shown in FIG. 5 (No in S215), the heat generating component a cannot be cooled simply by controlling the blocking shutters 24, 24a, and hence the air exhaust controlling circuit 17 increases the number of rotations of the bidirectional air exhaust fan 23 (S219). When the number of rotations of the bidirectional air exhaust fan 23 is increased, an air flow of a larger air volume can be supplied to the heat sink 21 on the side of the heat generating component a (the CPU 11), and the heat generating component a can be cooled. Then, the process returns to step S101 in which the air exhaust controlling circuit 17 again determines whether the temperature of the heat generating component b is higher than that of the heat generating component a or not.

In the case where it is necessary to cool the heat generating component a, if the heat generating component a can be cooled by adjusting the aperture ratios or operating the blocking shutters 24, 24a, the electronic apparatus 1 adjusts the aperture ratios or operates the blocking shutters 24, 24a to cool the heat generating component a. If not, the heat generating component a is cooled by increasing the number of rotations of the bidirectional air exhaust fan 23.

According to the first embodiment, the exhaust air volumes of the air exhaust ports 22, 22a of the bidirectional air exhaust fan 23 are dynamically controlled based on the temperatures of the heat generating components a, b to suppress unnecessary air exhaust and enhance the cooling efficiency, whereby the number of rotations of the air exhaust fan 23 can be maintained to an optimum state and the heat generating components a, b can be cooled.

### Second Embodiment

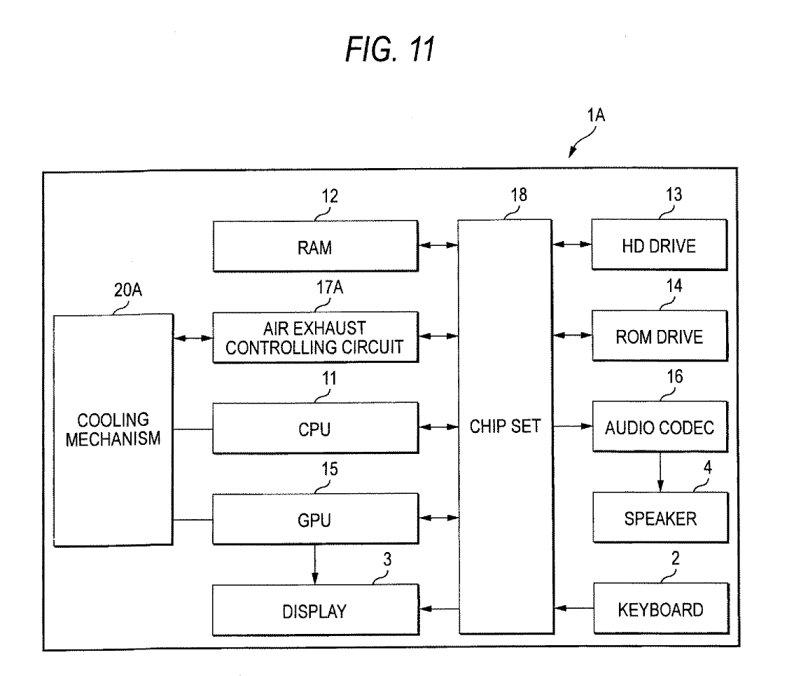

A second embodiment of the electronic apparatus of the invention will be described with reference to FIGS. 11 to 19. The components identical with those of the first embodiment are denoted by the same reference numerals, and duplicate description will be omitted. In the same manner as the electronic apparatus 1 of the first embodiment, the electronic apparatus 1A of the second embodiment is a notebook Personal Computer (PC) which is usually used, or the like. In the electronic apparatus 1A, as shown in FIG. 1, the keyboard 2 having a plurality of keys which are depressed when the user inputs instructions, the display device 3 which displays a screen showing characters, images, and the like, and the speaker 4 which outputs sounds are disposed so as to be exposed to the outside.

FIG. 11 is a block diagram of the electronic apparatus 1A. As shown in FIG. 11, the electronic apparatus 1A includes a Central Processing Unit (CPU) 11, a Random Access Memory (PAM) 12, a Hard Disk (HD) drive 13, a Read Only Memory (ROM) drive 14, a GPU 15, an audio codec 16, and an air exhaust controlling circuit 17A which controls a cooling mechanism 20A for the CPU 11 and the GPU 15. These components are interconnected by a chip set 18.

The air exhaust controlling circuit 17A controls a cooling mechanism 20A which cools heat generating components a, b such as the CPU 11 and the GPU 15. Specifically, the air exhaust controlling circuit 17A obtains the temperatures of the heat generating components a, b such as the CPU 11 and the CPU 15, and determines whether the heat generating components a, b are to be cooled or not, and, if it is determined that the heat generating components are to be cooled, performs an air exhaust control process of cooling the heat generating components a, b.

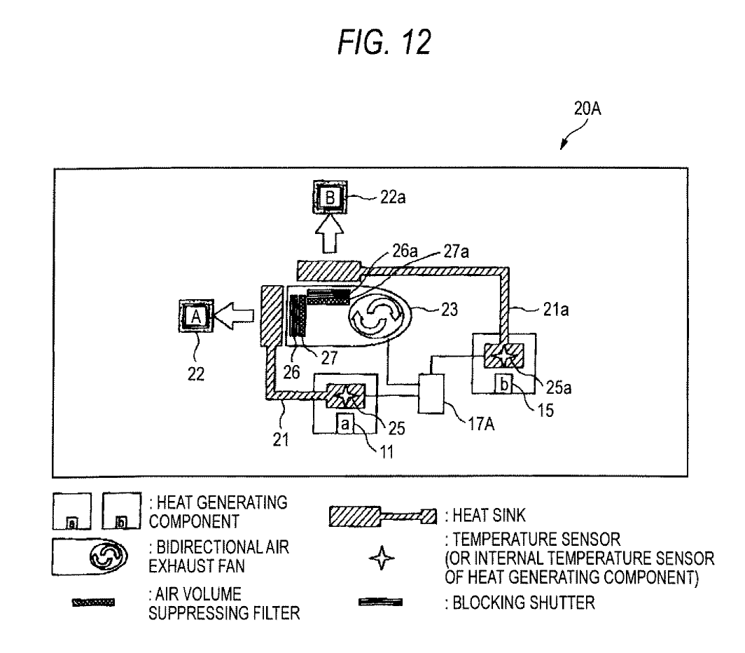

As shown in FIG. 12, the cooling mechanism 20A is a mechanism which, under the control of the air exhaust controlling circuit 17A, cools the heat generating components a, b such as the CPU 11 and the GPU 15. As shown in FIG. 12, the cooling mechanism 20A includes heat sinks 21, 21a for the heat generating components a, b, respectively. The heat generating components a, b are cooled by the heat sinks 21, 21a, respectively. The heat sink 21 is provided with an air exhaust port (A) 22 to blow hot air to the outside, and similarly the heat sink 21a is provided with an air exhaust port (B) 22a. The cooling mechanism 20A further includes a bidirectional air exhaust fan 23, so that the air blown by the bidirectional air exhaust fan 23 is passed over the heat sink 21 or the heat sink 21a and then exhausted from the respective air exhaust ports 22, 22a.

A blocking shutter 26 and an air volume suppressing filter 27 are disposed between the bidirectional air exhaust fan 23 and the heat sink 21, and a blocking shutter 26a and an air volume suppressing filter 27a are disposed between the bidirectional air exhaust fan 23 and the heat sink 21a. The blocking shutters 26, 26a are shutters which block the air flow blown from the bidirectional air exhaust fan 23, from flowing to the corresponding heat sink 21 or 21a. It is assumed that the blocking shutters 26, 26a can block 100% of the air volume.

The air volume suppressing filters 27, 27a are filters which suppress the air volume that is generated by the bidirectional air exhaust fan 23, and that flows to the corresponding heat sink 21 or 21a. A fine filter element is used in the air volume suppressing filters 27, 27a to increase the airflow resistance, whereby the air volume is suppressed. When the air volume suppressing filter 27 is placed on the side of the air exhaust port (A) 22, for example, the airflow resistance is made larger, and the wind pressure on the side of the air exhaust port (B) 22a is increased, with the result that the exhaust air volume on the side of the air exhaust port (B) 22a can be increased. Here, it is assumed that the air volume suppressing filters 27, 27a can suppress the air volume to 50%.

The cooling mechanism 20A includes temperature sensors 25, 25a in the vicinities of the heat generating components a, b such as the CPU 11 and the CPU 15, respectively. The air exhaust controlling circuit 17A obtains the temperature of the heat generating component a (the CPU 11) from the temperature sensor 25, and also that of the heat generating component b (the GPU 15) from the temperature sensor 25a. The temperature sensors 25, 25a may be incorporated in the heat generating components a, b such as the CPU 11 and the GPU 15. Based on the temperatures, the air exhaust controlling circuit 17A adjusts the set states of the blocking shutters 26, 26a and the air volume suppressing filters 27, 27a, or the number of rotations of the bidirectional air exhaust fan 23, whereby the heat generating components a, b are cooled while the exhaust air volumes to the heat sinks 21, 21a are adjusted.

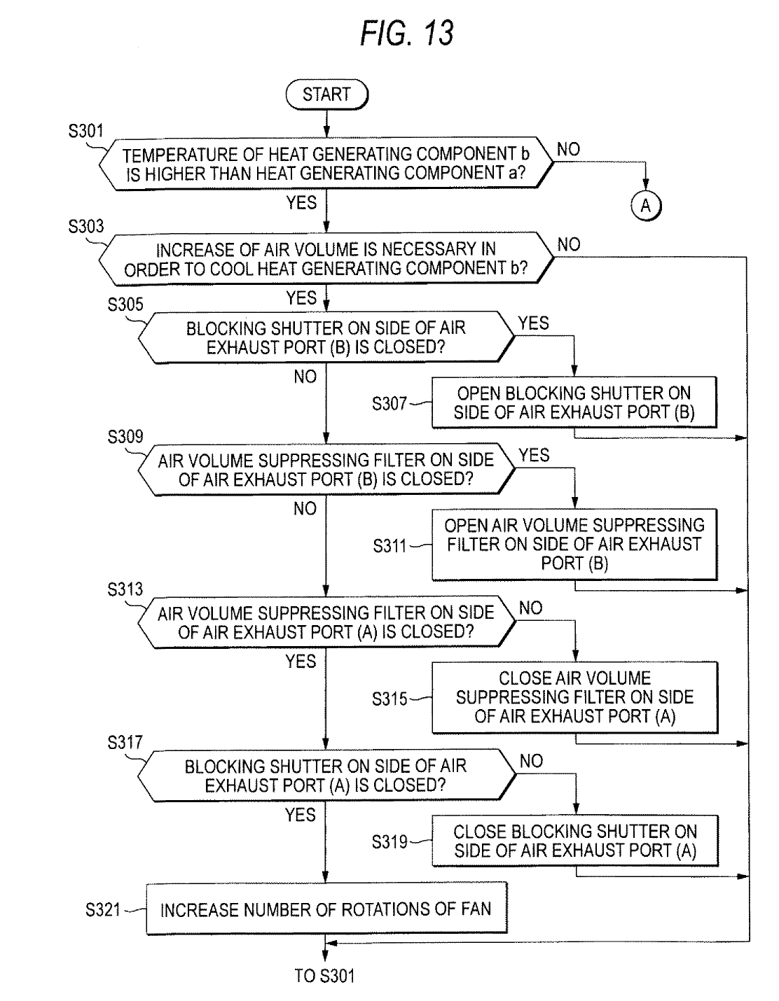

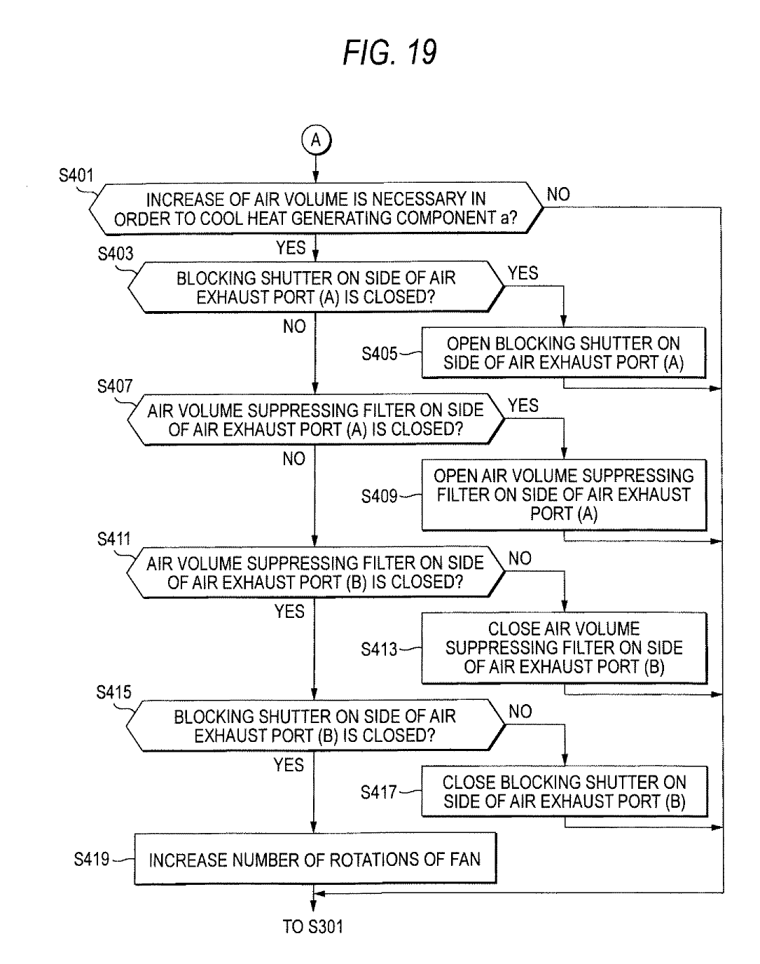

The electronic apparatus 1A obtains the temperatures of the heat generating components a, b such as the CPU 11 and the GPU 15, at, for example, regular intervals, and, based on the temperatures, performs the air exhaust control process in which the set states of the blocking shutters 26, 26a and the air volume suppressing filters 27, 27a are adjusted, or the air volume of the bidirectional air exhaust fan 23 is adjusted. The procedure in which the electronic apparatus 1A performs the air exhaust control process will be described with reference to the flowcharts shown in FIGS. 13 and 19.

Here, it is assumed that, when all of the blocking shutter 26 and the air volume suppressing filter 27 on the side of the air exhaust port (A) 22, and the blocking shutter 26a and the air volume suppressing filter 27a on the side of the air exhaust port (B) 22a are opened, an air flow of an air volume of 60% of an air flow generated by the bidirectional air exhaust fan 23 flows to the air exhaust port (A) 22, and an air flow of an air volume of 40% flows to the air exhaust port (B) 22a as shown in FIG. 16.

First, the air exhaust controlling circuit 17A determines whether the temperature of the heat generating component b (the GPU 15) is higher than that of the heat generating component a (the CPU 11) or not (S301). This determination is performed by the air exhaust controlling circuit 17A with obtaining the temperatures of the CPU 11 and the GPU 15 from the temperature sensors 25, 25a, and comparing the temperatures.

The case where the temperature of the heat generating component b (the CPU 15) is higher than that of the heat generating component a (the CPU 11) will be described with reference to the flowchart shown in FIG. 13. If the temperature of the heat generating component b is higher than that of the heat generating component a (Yes in S301), the air exhaust controlling circuit 17A determines whether it is necessary to increase the air volume in order to cool the heat generating component b or not (S303). In the case where the temperature of the heat generating component b is equal to or higher than a threshold value, for example, it is determined that the air volume is necessary to be increased.

If it is not necessary to increase the air volume for cooling the heat generating component b (No in S303), it is not necessary to cool the heat generating component a in which the temperature is lower than the heat generating component b, and hence the process returns to step S301 in which the air exhaust controlling circuit 17A again determines whether the temperature of the heat generating component b is higher than that of the heat generating component a or not.

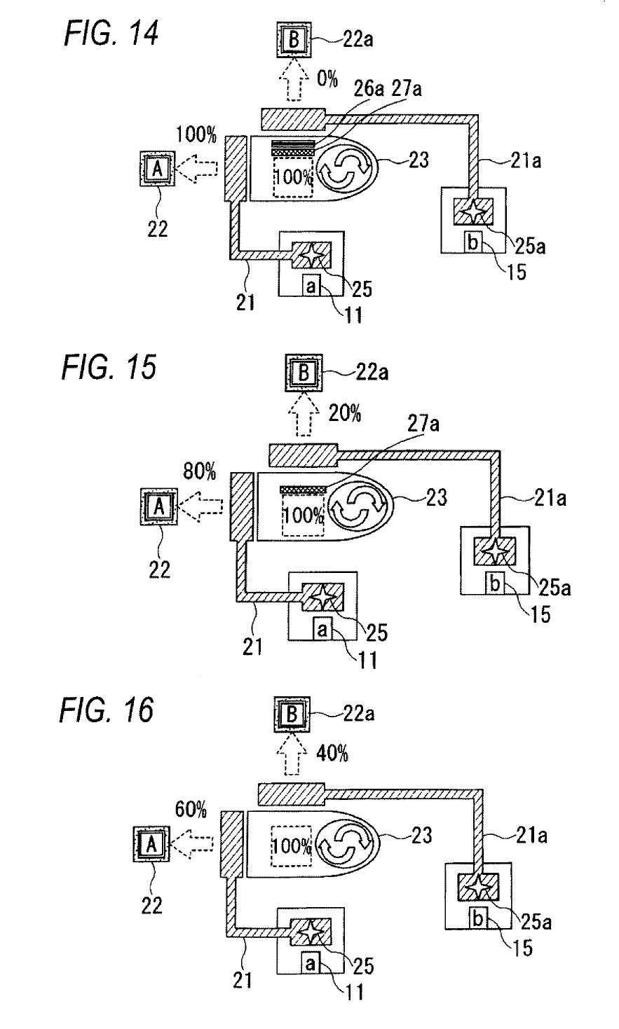

If it is necessary to increase the air volume for cooling the heat generating component b (Yes in S303), the air exhaust controlling circuit 17A determines whether the aperture ratio of the blocking shutter 26a on the side of the air exhaust port (B) 22a is 0% as shown in FIG. 14 or not, i.e., whether the blocking shutter 26a is completely closed or not, in order to seek means for cooling the heat generating component b without increasing the number of rotations of the bidirectional air exhaust fan 23 (S305). In this case, the air flow generated by the bidirectional air exhaust fan 23 does not flow to the air exhaust port (B) 22a by the blocking shutter 26a on the side of the air exhaust port (B) 22a, and hence an air flow of an air volume of 100% flows to the air exhaust port (A) 22.

If the blocking shutter 26a on the side of the air exhaust port (B) 22a is closed (Yes in S305), the air exhaust controlling circuit 17A opens the blocking shutter 26a (S307). As a result, as shown in FIG. 15, an air flow of an air volume of 80% flows to the air exhaust port (A) 22, and an air flow of 20% flows to the air exhaust port (B) 22a. In this way, when the blocking shutter 26a on the side of the air exhaust port (B) 22a is opened, an air flow of a larger air volume can be supplied to the heat sink 21a on the side of the heat generating component b (the GPU 15), and the heat generating component b can be cooled. Then, the process returns to step S301 in which the air exhaust controlling circuit 17A again determines whether the temperature of the heat generating component b is higher than that of the heat generating component a or not.

If the blocking shutter 26a on the side of the air exhaust port (B) 22a is not closed (No in 5305), the air exhaust controlling circuit 17A determines whether the air volume suppressing filter 27a on the side of the air exhaust port (B) 22a is closed as shown in FIG. 15 or not (S309). In this case, the air flow generated by the bidirectional air exhaust fan 23 hardly flows to the air exhaust port (B) 22a by the air volume suppressing filter 27a on the side of the air exhaust port (B) 22a. Therefore, an air flow of an air volume of 80% flows to the air exhaust port (A) 22, and an air flow of an air volume of 20% flows to the air exhaust port (B).

If the air volume suppressing filter 27a on the side of the air exhaust port (B) 22a is closed (Yes in S309), the air exhaust controlling circuit 17A opens the air volume suppressing filter 27a (S311). As a result, as shown in FIG. 16, an air flow of an air volume of 60% flows to the air exhaust port (A) 22, and an air flow of an air volume of 40% flows to the air exhaust port (B) 22a. In this way, when the air volume suppressing filter 27a on the side of the air exhaust port (B) 22a is completely opened, an air flow of a larger air volume can be supplied to the heat sink 21a on the side of the heat generating component b (the GPU 15), and the heat generating component b can be cooled. Then, the process returns to step S301 in which the air exhaust controlling circuit 17A again determines whether the temperature of the heat generating component b is higher than that of the heat generating component a or not.

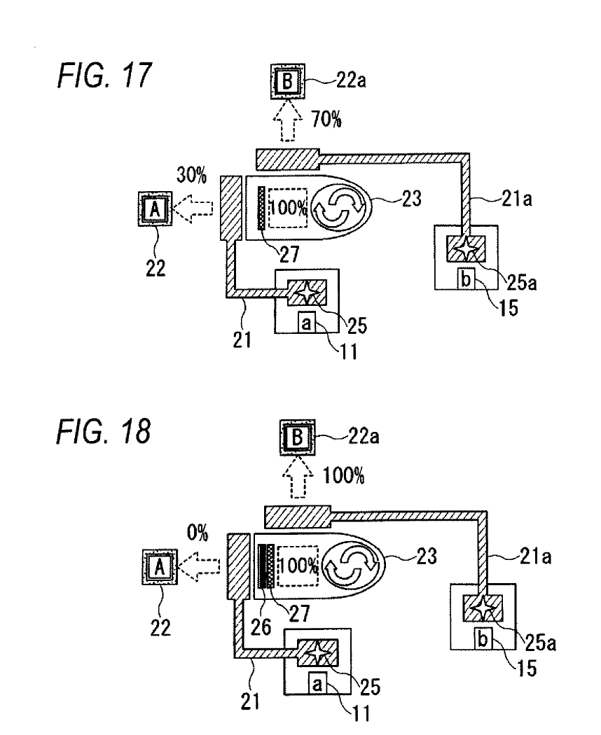

If the air volume suppressing filter 27a on the side of the air exhaust port (B) 22a is not closed (No in S309), the air exhaust controlling circuit 17A determines whether the air volume suppressing filter 27 on the side of the air exhaust port (A) 22 is closed as shown in FIG. 17 or not (S313). In this case, an air flow of an air volume of 60% flows to the air exhaust port (A) 22, and an air flow of an air volume of 40% flows to the air exhaust port (B) 22a.

If the air volume suppressing filter 27 on the side of the air exhaust port (A) 22 is not closed (No in S313), the air exhaust controlling circuit 17A closes the air volume suppressing filter 27 (S315). As a result, as shown in FIG. 17, an air flow of an air volume of 30% flows to the air exhaust port (A) 22, and an air flow of an air volume of 70% flows to the air exhaust port (B) 22a. In this way, when the air volume suppressing filter 27 on the side of the air exhaust port (A) 22 is closed to restrict the air volume blown to the air exhaust port (A) 22, an air flow of a larger air volume can be supplied to the heat sink 21a on the side of the heat generating component b (the GPU 15), and the heat generating component b can be cooled. Then, the process returns to step S301 in which the air exhaust controlling circuit 17A again determines whether the temperature of the heat generating component b is higher than that of the heat generating component a or not.

If the air volume suppressing filter 27 on the side of the air exhaust port (A) 22 is closed (Yes in S313), the air exhaust controlling circuit 17A determines whether the blocking shutter 26 on the side of the air exhaust port (A) 22 is closed as shown in FIG. 18 or not (S317). In this case, the air flow generated by the bidirectional air exhaust fan 23 does not flow to the air exhaust port (A) 22 by the blocking shutter 26 on the side of the air exhaust port (A) 22. Therefore, an air flow of an air volume of 100% flows to the air exhaust port (B) 22a.

If the blocking shutter 26 on the side of the air exhaust port (A) 22 is not closed (No in S317), the air exhaust controlling circuit 17A closes the blocking shutter 26 (S319). As a result, as shown in FIG. 18, an air flow of an air volume of 0% flows to the air exhaust port (A) 22, and an air flow of an air volume of 100% flows to the air exhaust port (B) 22a. In this way, when the blocking shutter 26 on the side of the air exhaust port (A) 22 is closed and the air flow to the air exhaust port (A) 22 is blocked, an air flow of a larger air volume can be supplied to the heat sink 21a on the side of the heat generating component b (the CPU 15), and the heat generating component b can be cooled. Then, the process returns to step S301 in which the air exhaust controlling circuit 17A again determines whether the temperature of the heat generating component b is higher than that of the heat generating component a or not.

If the blocking shutter 26 on the side of the air exhaust port (A) 22 is closed (Yes in S317), the heat generating component b cannot be cooled simply by controlling the blocking shutters 26, 26a and the air volume suppressing filters 27, 27a, and hence the air exhaust controlling circuit 17A increases the number of rotations of the bidirectional air exhaust fan 23 (S321). When the number of rotations of the bidirectional air exhaust fan 23 is increased, an air flow of a larger air volume can be supplied to the heat sink 21a for the heat generating component b (the GPU 15), and the heat generating component b can be cooled. Then, the process returns to step S301 in which the air exhaust controlling circuit 17A again determines whether the temperature of the heat generating component b is higher than that of the heat generating component a or not.

In the case where it is necessary to cool the heat generating component b, if the heat generating component b can be cooled by controlling the set states of the blocking shutters 26, 26a and the air volume suppressing filters 27, 27a, the electronic apparatus 1A controls the set states of the blocking shutters 26, 26a and the air volume suppressing filters 27, 27a to cool the heat generating component b. If not, the heat generating component b is cooled by increasing the number of rotations of the bidirectional air exhaust fan 23.

Next, the case where the temperature of the heat generating component a (the CPU 11) is higher than that of the heat generating component b (the GPU 15) will be described with reference to the flowchart shown in FIG. 19. If the temperature of the heat generating component a is higher than that of the heat generating component b (No in S301), the air exhaust controlling circuit 17A determines whether it is necessary to increase the air volume for cooling the heat generating component a or not (S401). In the case where the temperature of the heat generating component b is equal to or higher than a threshold value, for example, it is determined that an increase of the air volume is necessary.

If it is not necessary to increase the air volume for cooling the heat generating component a (No in S401), it is not necessary to cool the heat generating component b in which the temperature is lower than the heat generating component a, and hence the process returns to step S301 in which the air exhaust controlling circuit 17A again determines whether the temperature of the heat generating component b is higher than that of the heat generating component a or not.

If it is necessary to increase the air volume for cooling the heat generating component a (Yes in S401), the air exhaust controlling circuit 17A determines whether the blocking shutter 26 on the side of the air exhaust port (A) 22 is closed as shown in FIG. 18 or not, in order to seek means for cooling the heat generating component a without increasing the number of rotations of the bidirectional air exhaust fan 23 (S403). In this case, the air flow generated by the bidirectional air exhaust fan 23 does not flow to the air exhaust port (A) 22 by the blocking shutter 26 on the side of the air exhaust port (A) 22, and hence an air flow of an air volume of 100% flows to the air exhaust port (B) 22a.

If the blocking shutter 26 on the side of the air exhaust port (A) 22 is closed (Yes in S403), the air exhaust controlling circuit 17A opens the blocking shutter 26 (S405). As a result, as shown in FIG. 17, an air flow of 30% flows to the air exhaust port (A) 22, and an air flow of an air volume of 70% flows to the air exhaust port (B) 22a. In this way, when the blocking shutter 26 on the side of the air exhaust port (A) 22 is opened, an air flow of a larger air volume can be supplied to the heat sink 21 on the side of the heat generating component a (the CPU 11), and the heat generating component a can be cooled. Then, the process returns to step S301 in which the air exhaust controlling circuit 17A again determines whether the temperature of the heat generating component b is higher than that of the heat generating component a or not.

If the blocking shutter 26 on the side of the air exhaust port (A) 22 is not closed (No in S403), the air exhaust controlling circuit 17A determines whether the air volume suppressing filter 27 on the side of the air exhaust port (A) 22 is closed as shown in FIG. 17 or not (S407). In this case, the air flow generated by the bidirectional air exhaust fan 23 hardly flows to the air exhaust port (A) 22 by the air volume suppressing filter 27 on the side of the air exhaust port (A) 22. Therefore, an air flow of an air volume of 30% flows to the air exhaust port (A) 22, and an air flow of an air volume of 70% flows to the air exhaust port (B) 22a.

If the air volume suppressing filter 27 on the side of the air exhaust port (A) 22 is closed (Yes in S407), the air exhaust controlling circuit 17A opens the air volume suppressing filter 27 (S409). As a result, as shown in FIG. 16, an air flow of an air volume of 60% flows to the air exhaust port (A), and an air flow of 40% flows to the air exhaust port (B). In this way, when the air volume suppressing filter 27 on the side of the air exhaust port (A) 22 is completely opened, an air flow of a larger air volume can be supplied to the heat sink 21 on the side of the heat generating component a (the CPU 11), and the heat generating component a can be cooled. Then, the process returns to step S301 in which the air exhaust controlling circuit 17A again determines whether the temperature of the heat generating component b is higher than that of the heat generating component a or not.

If the air volume suppressing filter 27 on the side of the air exhaust port (A) 22 is not closed (No in S407), the air exhaust controlling circuit 17A determines whether the air volume suppressing filter 27a on the side of the air exhaust port (B) 22a is closed as shown in FIG. 15 or not (S411). In this case, an air flow of an air volume of 80% flows to the air exhaust port (A), and an air flow of an air volume of 20% flows to the air exhaust port (B).

If the air volume suppressing filter 27a on the side of the air exhaust port (B) 22a is not closed (No in S411), the air exhaust controlling circuit 17A closes the air volume suppressing filter 27a (S413). As a result, as shown in FIG. 15, an air flow of an air volume of 80% flows to the air exhaust port (A), and an air flow of an air volume of 20% flows to the air exhaust port (B). In this way, when the air volume suppressing filter 27a on the side of the air exhaust port (B) 22a is closed to restrict the air volume blown to the air exhaust port (B) 22a, an air flow of a larger air volume can be supplied to the heat sink 21 on the side of the heat generating component a (the CPU 11), and the heat generating component a can be cooled. Then, the process returns to step S301 in which the air exhaust controlling circuit 17A again determines whether the temperature of the heat generating component b is higher than that of the heat generating component a or not.

If the air volume suppressing filter 27a on the side of the air exhaust port (B) 22a is closed (Yes in S411), the air exhaust controlling circuit 17A determines whether the blocking shutter 26a on the side of the air exhaust port (B) 22a is closed as shown in FIG. 14 or not (S415). In this case, the air flow generated by the bidirectional air exhaust fan 23 does not flow to the air exhaust port (B) 22a by the blocking shutter 26a on the side of the air exhaust port (B) 22a. Therefore, an air flow of an air volume of 100% flows to the air exhaust port (A), and an air flow of an air volume of 0% flows to the air exhaust port (B).

If the blocking shutter 26a on the side of the air exhaust port (B) 22a is not closed (No in S415), the air exhaust controlling circuit 17A closes the blocking shutter 26a (S417). As a result, as shown in FIG. 14, an air flow of an air volume of 100% flows to the air exhaust port (A) 22, and an air flow of an air volume of 0% flows to the air exhaust port (B) 22a. In this way, when the blocking shutter 26a on the side of the air exhaust port (B) 22a is completely closed and the air flow to the air exhaust port (B) 22a is blocked, an air flow of a larger air volume can be supplied to the heat sink 21 on the side of the heat generating component a (the CPU 11), and the heat generating component a can be cooled. Then, the process returns to step S301 in which the air exhaust controlling circuit 17A again determines whether the temperature of the heat generating component b is higher than that of the heat generating component a or not.

If the blocking shutter 26a on the side of the air exhaust port (B) 22a is closed (Yes in S415), the heat generating component a cannot be cooled simply by controlling the blocking shutters 26, 26a and the air volume suppressing filters 27, 27a, and hence the air exhaust controlling circuit 17A increases the number of rotations of the bidirectional air exhaust fan 23 (S419). When the number of rotations of the bidirectional air exhaust fan 23 is increased, an air flow of a larger air volume can be supplied to the heat sink 21 on the side of the heat generating component a (the CPU 11), and the heat generating component a can be cooled. Then, the process returns to step S301 in which the air exhaust controlling circuit 17A again determines whether the temperature of the heat generating component b is higher than that of the heat generating component a or not.

In the case where it is necessary to cool the heat generating component a, if the heat generating component a can be cooled by controlling the set states of the blocking shutters 26, 26a and the air volume suppressing filters 27, 27a, the electronic apparatus 1A controls the set states of the blocking shutters 26, 26a and the air volume suppressing filters 27, 27a, to cool the heat generating component a. If not, the heat generating component a is cooled by increasing the number of rotations of the bidirectional air exhaust fan 23.

According to the second embodiment, the exhaust air volumes of the air exhaust ports 22, 22a of the bidirectional air exhaust fan 23 are dynamically controlled based on the temperatures of the heat generating components a, b to suppress unnecessary air exhaust and enhance the cooling efficiency, whereby the number of rotations of the air exhaust fan 23 can be maintained to an optimum state and the heat generating components a, b can be cooled.

Although the electronic apparatuses 1, 1A of the invention have been described in the case where the function of implementing the invention is previously stored in the apparatuses, the invention is not restricted to this. A similar function may be downloaded from a network to the apparatus, or a recording medium on which the similar function is stored may be installed on the apparatus. As the recording medium, a medium of any form such as a CD-ROM may be used as far as it can store programs and can be read by the apparatus.

What is claimed is:

1. An electronic apparatus comprising:
a plurality of heat generating components;
a plurality of heat sinks respectively provided for the plurality of heat generating components;
a fan that simultaneously blows air to the heat sinks;
a plurality of shutters that respectively block air flows blown from the fan to the heat sinks;
a determining section configured to, based on temperatures of the heat generating components, determine whether one of the heat generating components needs to be cooled or not; and
a controlling section configured to operate at least one of the shutters to control air volume blown over one of the heat sinks that corresponds to the one of the heat generating components that needs to be cooled.

2. The apparatus according to claim 1, wherein:
the heat generating components include a first component and a second component; and
when the determining section determines that the first component needs to be cooled, the controlling section opens a shutter for the first component to control the air volume.

3. The apparatus according to claim 1, wherein:
the heat generating components include a first component and a second component; and
when the determining section determines that the first component needs to be cooled, the controlling section closes a shutter for the second component to control the air volume.

4. The apparatus according to claim 1, wherein:
the heat generating components include a first component and a second component; and
when the determining section determines that the first component needs to be cooled, while a shutter for the first component is opened and a shutter for the second component is closed, the controlling section increases the number of rotations of the fan to control the air volume.

5. The apparatus according to claim 1, wherein:
the shutters include a shutter in which an aperture ratio is adjustable; and
the controlling section adjusts the aperture ratio to control the air volume.

6. The apparatus according to claim 5, wherein;
the heat generating components include a first component and a second component; and
when the determining section determines that the first component needs to be cooled, the controlling section increases the aperture ratio of a shutter for the first component to control the air volume.

7. The apparatus according to claim 5, wherein:
the heat generating components include a first component and a second component; and
when the determining section determines that the first component needs to be cooled, the controlling section decreases the aperture ratio of a shutter for the second component to control the air volume.

8. The apparatus according to claim 5, wherein:
the heat generating components include a first component and a second component; and
when the determining section determines that the first component needs to be cooled, while the aperture ratio of a shutter for the first component is 100% and the aperture ratio of a shutter for the second component is 0%, the controlling section increases the number of rotations of the fan to control the air volume.

9. An electronic apparatus comprising:
a plurality of heat generating components;
a plurality of heat sinks respectively provided for the plurality of heat generating components;
a fan that simultaneously blows air to the heat sinks;
a plurality of shutters that respectively block air flows blown from the fan to the heat sinks;
a plurality of filters that respectively suppress air volumes blown from the fan to the heat sinks;
a determining section configured to, based on temperatures of the heat generating components, determine whether one of the heat generating components needs to be cooled or not; and
a controlling section configured to operate at least one of the shutters and the filters to control air volume blown over one of the heat sinks that corresponds to the one of the heat generating components that needs to be cooled.

10. The apparatus according to claim 9, wherein:
the heat generating components include a first component and a second component; and
when the determining section determines that the first component needs to be cooled, the controlling section opens a shutter for the first component to control the air volume.

11. The apparatus according to claim 9, wherein:
the heat generating components include a first component and a second component; and
when the determining section determines that the first component needs to be cooled, the controlling section opens a filter for the first component to control the air volume.

12. The apparatus according to claim 9, wherein:
the heat generating components include a first component and a second component; and
when the determining section determines that the first component needs to be cooled, the controlling section closes a shutter for the second component to control the air volume.

13. The apparatus according to claim 9, wherein:
the heat generating components include a first component and a second component; and
when the determining section determines that the first component needs to be cooled, the controlling section closes a filter for the second component to control the air volume.

14. The apparatus according to claim 9, wherein:
the heat generating components include a first component and a second component; and
when the determining section determines that the first component needs to be cooled, while a shutter and a filter for the first component are opened and a shutter and a filter for the second component are closed, the controlling section increases the number of rotations of the fan to control the air volume.
